(19) United States
(12) Patent Application Publication
(10) Pub. No.: US 2026/0238185 A1
(43) Pub. Date: Aug. 13, 2026

(54) PIEZOELECTRIC ACOUSTIC LAMB WAVE RESONATORS HAVING MASS LOADING FRAMES FOR SPURIOUS MODE SUPPRESSION

(71) Applicant: MACOM Technology Solutions Holdings, Inc., Lowell, MA (US)

(72) Inventor: Renyuan Wang, Windham, NH (US)

(21) Appl. No.: 19/424,270

(22) Filed: Dec. 18, 2025

Related U.S. Application Data
(60) Provisional application No. 63/755,439, filed on Feb. 7, 2025.

(51) Int. Cl. H03H 9/17; H03H 3/02; H03H 9/05

(52) U.S. Cl. CPC H03H 9/17; H03H 3/02; H03H 9/05

(57) ABSTRACT

An acoustic lamb wave resonator comprises a substrate having a recess, a piezoelectric layer that at least partially covers the recess, a plurality of metal electrodes on the piezoelectric layer, each metal electrode comprising a first metal, and a plurality of second metal segments that comprise a second metal that is different than the first metal, the second metal segments on respective ones of at least some of the metal electrodes opposite the piezoelectric layer.

The present application claims priority under 35 U.S.C. § 119 to U.S. Provisional Patent Application Ser. No. 63/755,439, filed Feb. 7, 2025, the entire content of which is incorporated herein by reference as if set forth in its entirety.

### FIELD

The present application relates to filters and, more particularly, to acoustic lamb wave radio frequency (“RF”) filters formed using one or more lamb wave resonators.

### BACKGROUND

RF acoustic wave filters are indispensable in modern RF electronic systems due to their compact size and high performance. In particular, thin film aluminum nitride and scandium aluminum nitride based bulk acoustic wave filters (“BAW filters”) can provide high performance and are very small. One disadvantage of BAW filters, however, is that because the acoustic waves travel perpendicularly to the major surfaces of the device substrate (i.e., in the thickness direction of the device), the center frequency of the device is based on the thickness of the piezoelectric film that forms the acoustic wave resonant cavity. In addition, scaling BAW resonators and filters below 1.5 GHz poses microfabrication challenges and provides marginal performance benefits against alternative technologies. While the acoustic waves in a surface acoustic wave filter (“SAW filter”) travel parallel to the major surfaces of the substrate so that their center frequencies are based on the distances between adjacent surface electrodes, and hence can be defined by photolithography, SAW filters exhibit degraded performance as compared to BAW filters, since the surface travelling wave couples to substrate bulk modes and thus leads to acoustic energy leakage.

RF acoustic lamb wave resonators and filters are an amalgamation of BAW filters and SAW filters. An acoustic lamb wave filter comprises a piezoelectric membrane that is suspended above a substrate, and the acoustic wave travels laterally (i.e., parallel to the substrate) in the piezoelectric film. As such, the filter frequencies may be defined via photolithography, as is the case with SAW filters. Moreover, since the piezoelectric film is suspended above a recess in the substrate, the acoustic wave is decoupled from the substrate and hence acoustic loss from energy radiation into the substrate may be very low. This allows RF acoustic lamb wave resonators and filters to exhibit quality factors that are similar to those provided by BAW filters. Similar to other acoustic wave filter technologies, RF acoustic lamb wave resonators may generate strong spurious resonant modes that may fall near the primary resonances. These spurious resonant modes can degrade the performance of the filter. It may be important to suppress these spurious modes with minimum degradation of other resonator and filter performance parameters.

Acoustic filters such as acoustic lamb wave filters are typically formed of a plurality of acoustic lamb wave resonators that are electrically interconnected to each other (e.g., in parallel and/or in series). Thus, while the present disclosure focuses on acoustic lamb wave resonators, it will be appreciated that a wide variety of acoustic lamb wave filters may be formed using the acoustic lamb wave resonators disclosed herein.

### SUMMARY

Pursuant to embodiments of the present invention, an acoustic lamb wave resonator is provide that comprises a substrate having a recess, a piezoelectric layer that at least partially covers the recess, a plurality of metal electrodes on the piezoelectric layer, each metal electrode comprising a first metal, and a plurality of second metal segments that comprise a second metal that is different than the first metal, the second metal segments on respective ones of at least some of the metal electrodes opposite the piezoelectric layer.

In some embodiments, the acoustic lamb wave resonator has an active region and an inactive region, and the metal electrodes are within the active region. In some embodiments, the first metal comprises aluminum. In some embodiments, the second metal comprises tungsten. In some embodiments, the second metal segments form a frame.

In some embodiments, the acoustic lamb wave resonator further comprises a signal bus and a ground bus, and the plurality of metal electrodes comprise a plurality of signal electrodes that are physically and electrically connected to the signal bus and a plurality of ground electrodes that are physically and electrically connected to the ground bus. In some embodiments, a first subset of the second metal segments are on distal ends of the respective signal electrodes, a second subset of the second metal segments are on base regions of the respective signal electrodes, a third subset of the second metal segments are on distal ends of the respective ground electrodes, and a fourth subset of the second metal segments are on base regions of the respective ground electrodes. In some embodiments, the second metal segments in the first subset and the fourth subset are aligned along a first axis, and the second metal segments in the second subset and the third subset are aligned along a second axis. In some embodiments, the first axis and the second axis extend in parallel to each other.

In some embodiments, the acoustic lamb wave resonator further comprises a first plurality of floating electrodes on the piezoelectric layer and a second plurality of floating electrodes on the piezoelectric layer on respective opposed sides of the active region, each floating electrode comprising the first metal. In such embodiments, the acoustic lamb wave resonator may also comprise a supplemental metal frame, the supplemental metal frame comprising a plurality of additional second metal segments, where each additional second metal segment comprises the second metal and is on a respective one of the floating electrodes opposite the piezoelectric layer. In some embodiments, each second metal segment completely covers a respective one of the floating electrodes.

In some embodiments, each of the metal electrodes extends along a respective longitudinal axis, where the longitudinal axes extend in a length direction of the acoustic lamb wave resonator, and a length of each second metal segment in the length direction is set so that displacement profiles of the spurious modes at the end of the frame exhibit a mechanical anti-node.

In some embodiments, the second metal has a higher density than the first metal. In some embodiments, the second metal may additionally or alternatively have a higher resistivity than the first metal.

In some embodiments, each of the metal electrodes extends along a respective longitudinal axis, where the longitudinal axes extend in a length direction of the acoustic lamb wave resonator, and wherein each second metal segment is stacked on a respective one of the metal electrodes in a depth direction and has a width in a width direction that is the same as the width of the metal electrode on which it is stacked, where the length, width and depth directions are perpendicular to each other.

In some embodiments, each second metal segment is in between a respective one of the metal electrodes and the piezoelectric layer, and each second metal segment directly contacts both the respective one of the metal electrodes and the piezoelectric layer.

Pursuant to further embodiments of the present invention, an acoustic lamb wave resonator is provided that comprises a substrate having a recess, a piezoelectric layer that at least partially covers the recess, a plurality of metal electrodes on the piezoelectric layer, the metal electrodes defining an active region, and a first metal frame section on a first side of the active region, the first metal frame section comprising a first plurality of spaced-apart frame segments on respective ones of the metal electrodes.

In some embodiments, each metal electrode comprises a first metal, and each frame segment comprises a second metal that is different than the first metal. In some embodiments, the second metal has a higher density than the first metal. In some embodiments, the second metal has a higher resistivity than the first metal.

In some embodiments, the acoustic lamb wave resonator further comprises a second metal frame section on a second side of the active region that is opposite the first side, the second metal frame section comprising a second plurality of spaced-apart frame segments on respective ones of the metal electrodes. In some embodiments, each metal electrode is in between a respective one of the frame segments in the first plurality of spaced-apart frame segments and the piezoelectric layer.

Pursuant to further embodiments of the present invention, an acoustic lamb wave resonator is provided that comprises a substrate having a recess, a piezoelectric layer that at least partially covers the recess, where the piezoelectric layer includes an active region and an inactive region, and a plurality multi-layer metal structures on the piezoelectric layer in the active region, where each multi-layer metal structure includes a first layer that comprises a first metal that directly contacts the piezoelectric layer and a second layer that comprises a second metal that is different than the first metal on the first layer opposite the piezoelectric layer.

In some embodiments, the second layer only partially covers the first layer. In some embodiments, the second metal has a higher density than the first metal. In some embodiments, the first layer comprises a plurality of electrodes, and the second layer comprises a plurality of metal segments that are formed on opposed ends of each electrode.

Pursuant to further embodiments of the present invention, a method of fabricating an acoustic lamb wave resonator is provided in which a piezoelectric layer is provided (e.g., formed) on a substrate, a first metal layer is formed on the piezoelectric layer, a second metal layer is formed on the first metal layer, a first mask structure is formed on the second metal layer, the first and second metal layers are patterned using the mask as a first patterning mask, a second mask structure is formed on the piezoelectric layer and on the second metal layer, and the second metal layer is patterned using the second mask structure as a second patterning mask.

In some embodiments, the first metal layer comprises aluminum, copper and/or platinum and the second metal layer comprises tungsten and/or molybdenum. In some embodiments, the method further comprises forming a recess in the piezoelectric layer and filling the recess with a sacrificial material prior to forming the first metal layer. In some embodiments, the first metal layer is also formed on the sacrificial material. In some embodiments, the first mask structure is a first photolithography mask and wherein patterning the first and second metal layers using the mask as a first patterning mask comprises etching both the first metal layer and the second metal layer using the first photolithography mask as an etch mask.

In some embodiments, forming the first metal layer on the piezoelectric layer comprises blanket depositing the first metal layer on the piezoelectric layer, and wherein forming the second metal layer on the first metal layer comprises blanket depositing the second metal layer on the first metal layer. In some embodiments, the second mask structure is a second photolithography mask and wherein patterning the second metal layer using the second mask structure as the second patterning mask comprises etching the second metal layer using the second photolithography mask as an etch mask with an etchant that selectively etches a second material of the second metal layer without etching a first material of the first metal layer. In some embodiments, the patterned second metal layer comprises a frame that is configured to suppress spurious modes of the acoustic lamb wave resonator.

### BRIEF DESCRIPTION OF THE DRAWING

FIG. 1A is a schematic top perspective view of an active region of a conventional acoustic lamb wave resonator.

FIG. 1B is a schematic top view of the acoustic lamb wave resonator of FIG. 1A.

FIG. 1C is a schematic cross-sectional view taken along line 1C-1C of FIG. 1B.

FIG. 2A is a schematic diagram showing the acoustic waves that are generated within the piezoelectric film in the active region of a conventional acoustic lamb wave resonator.

FIG. 2B is a graph illustrating the results of a finite element simulation of a conventional acoustic lamb wave resonator.

FIG. 3A is a schematic top view of an acoustic lamb wave resonator according to embodiments of the present invention.

FIGS. 3B and 3C are schematic cross-sectional views taken along lines 3B-3B and 3C-3C, respectively, of FIG. 3A.

FIG. 4 is a schematic diagram that illustrates details of a technique according to embodiments of the present invention for spurious mode suppression using a mass-loaded frame.

FIG. 5 is a graph that illustrates how the acoustic wave lamb filters according to embodiments of the present invention may suppress spurious modes.

FIGS. 6A-6B are cross-sectional views that illustrate certain steps of a microfabrication process for manufacturing acoustic wave lamb filters according to embodiments of the present invention, and FIGS. 6C-6F each include a schematic top view and a schematic cross-sectional view to illustrate further steps of the microfabrication process for manufacturing acoustic wave lamb filters according to embodiments of the present invention.

Two-part reference numerals may be used herein to refer to at least some of the elements of the acoustic wave lamb filters according to embodiments of the present invention that comprise multiple like elements. Herein, such elements may be referred to individually by their full reference numeral and collectively by the first part of their reference numerals.

The dimensions of various layers and elements in the figures may not be drawn to scale.

### DETAILED DESCRIPTION

Pursuant to embodiments of the present invention, RF acoustic lamb wave resonators are provided that have significantly reduced spurious resonances. The acoustic lamb wave resonators disclosed herein may be used to form a wide variety of acoustic lamb wave filters. The acoustic lamb resonators according to embodiments of the present invention may have a metal frame that is formed on, for example, the signal and ground electrodes opposite the piezoelectric film. The metal frame acts to increase the mass-loading of the piezoelectric film in the region of the frame, minimizing the energy coupling into spurious modes, thereby achieving spurious mode suppression.

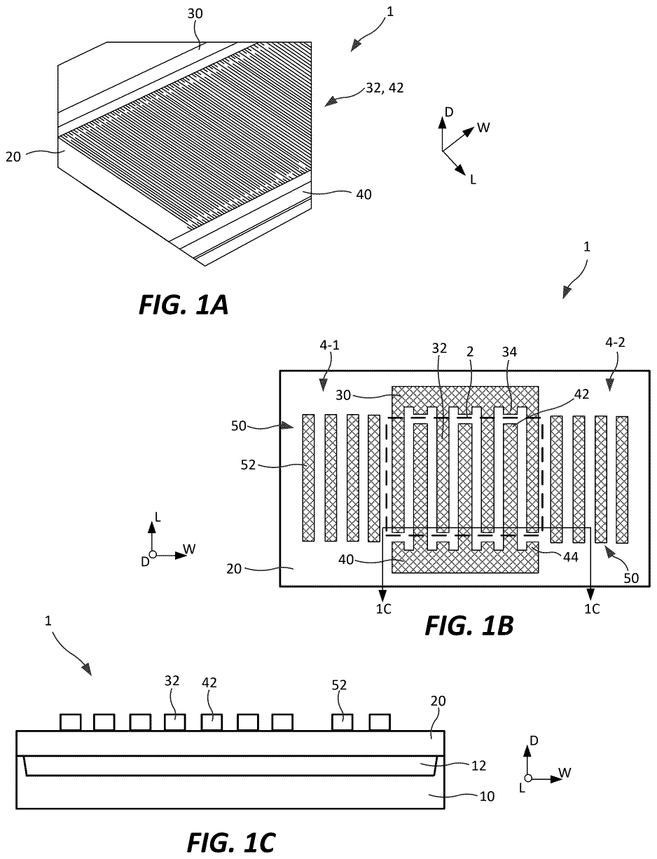

FIGS. 1A-1C schematically illustrate a conventional acoustic lamb wave resonator 1. In particular, FIG. 1A is a schematic top perspective view of an active region of the acoustic lamb wave resonator 1. FIG. 1B is a schematic top view of the acoustic lamb wave resonator 1 of FIG. 1A that illustrates how the active region is bordered on opposed sides by inactive regions that include grating reflectors. Finally, FIG. 1C is a schematic cross-sectional view taken along line 1C-1C of FIG. 1B. It should be noted that in the schematic views of FIGS. 1B and 1C, only a few of the electrode pairs that are formed in the active region are shown to simplify these figures. Typically, there will be a much larger number of electrodes, as is shown in FIG. 1A.

As shown in FIGS. 1A-1C, the acoustic lamb wave resonator 1 includes a substrate 10 that has an air-filled recess 12 formed in an upper surface thereof. The substrate 10 may comprise a silicon substrate. A thin piezoelectric film 20 such as a scandium aluminum nitride film is provided above the recess 12. A metal signal bus 30 and a metal ground bus 40 are formed on an upper surface of the thin piezoelectric film 20. A plurality of signal electrodes 32 extend from the signal bus 30 toward the ground bus 40, and a plurality of ground electrodes 42 extend from the ground bus 40 toward the signal bus 30. The signal bus 30 and the ground bus 40 may extend in parallel to each other with their respective longitudinal axes extending in a “width” direction W of the acoustic lamb wave resonator 1. The signal electrodes 32 and the ground electrodes 42 may extend in parallel to each other with their respective longitudinal axes extending in a “length” direction L of the acoustic lamb wave resonator 1, where the length direction L is perpendicular to the width direction W. A depth direction D of the acoustic lamb wave resonator 1 extends perpendicularly to the width and length directions W, L (and hence perpendicular to the major surfaces of the thin piezoelectric film 20. It should be noted that the extent of an acoustic lamb wave resonator may be greater in the width direction W than in the length direction L.

The signal and ground electrodes 32, 42 may be much longer in the length direction than in the width direction (e.g., the length of each signal and ground electrode 32, 42 may be twenty to two hundred times its width in example embodiments). The signal bus 30 may further include a plurality of signal stubs 34 that extend a short distance toward the ground bus 40. Each signal stub 34 may be aligned in the length direction L with a respective one of the ground electrodes 42. Similarly, the ground bus 40 may further include a plurality of ground stubs 44 that extend a short distance toward the signal bus 30. Each ground stub 44 may be aligned in the length direction L with a respective one of the signal electrodes 32.

The signal bus, 30, the ground bus 40, and the outer ones of the signal/ground electrodes 32, 42 define an active region 2 of the acoustic lamb wave resonator 1. The active region is shown in FIG. 1B by the dashed box. Inactive regions 4-1 and 4-2 are provided on opposed sides of the active region 2. A plurality of electrically floating metal electrodes 52 are provided in each inactive region 4. Each floating electrode 52 has a longitudinal axis that extends in the length direction L, and lengths of the floating electrodes 52 may (but need not) be the same as or similar to the lengths of signal electrodes 32 and the ground electrodes 42. The floating metal electrodes 52 may (but need not) have the same pitch as the signal/ground electrodes 32/42 in the active region 2, and form an acoustic grating reflector 50 in each inactive region 4-1, 4-2. The acoustic grating reflectors 50 enhance confinement of acoustic energy within the active region 2.

The signal electrodes 32 and the ground electrodes 42 are spaced apart from one another in the width direction in alternating fashion so that (except at the opposed side edges of the active region 2) a ground electrode 42 is provided on either side of each signal electrode 32, and a signal electrode 32 is provided on either side of each ground electrode 42. In other words, the signal electrodes 32 and the ground electrodes 42 are disposed in alternating fashion on the piezoelectric film 20.

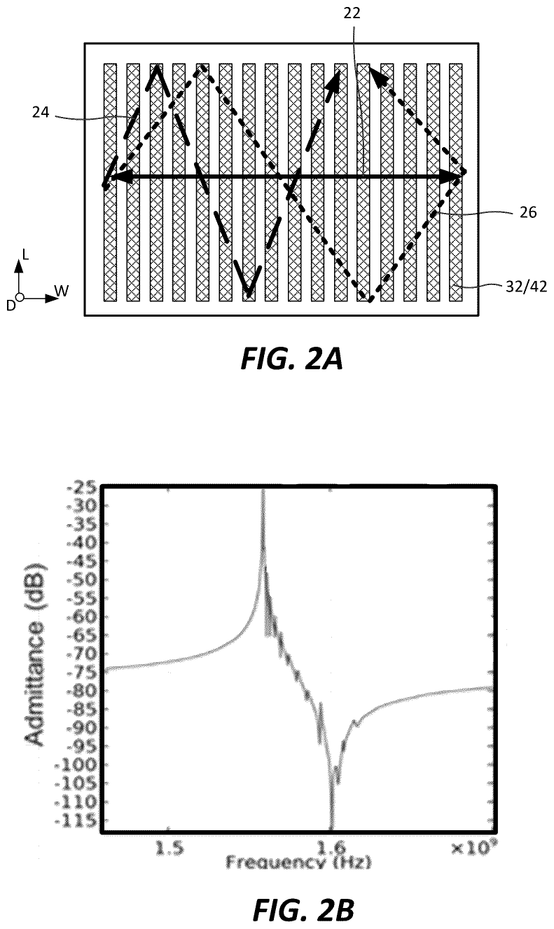

FIG. 2A is a schematic diagram showing the acoustic waves that are generated within the piezoelectric film 20 in the active region 2 during operation of the acoustic lamb wave resonator 1. FIG. 2B is a graph illustrating the results of a finite element simulation of a conventional acoustic lamb wave resonator. As shown in FIG. 2A, the wave propagation direction 22 associated with the primary resonance is in the width direction W. Unfortunately, however, higher order spurs are generated that have respective wave propagation directions 24, 26 that are angled with respect to both the width direction W and the length direction L so that they “bounce” between the signal bus 30 and the ground bus 40. As shown in FIG. 2B, these “spurious” resonances create significant ripples in the resonator response that may degrade the performance thereof.

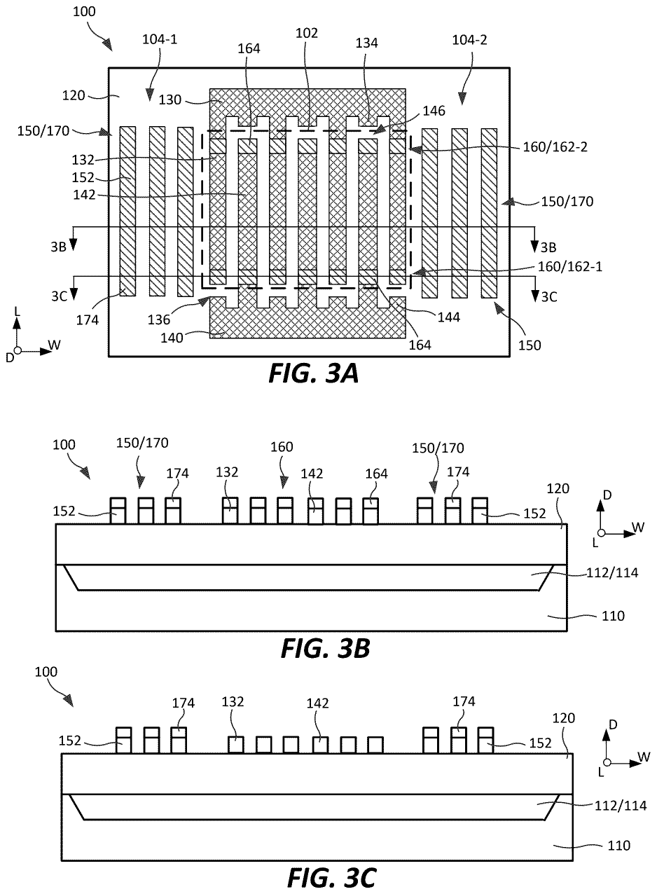

FIGS. 3A-3C schematically illustrate an acoustic lamb wave resonator 100 according to embodiments of the present invention. In particular, FIG. 3A is a schematic top view of the acoustic lamb wave resonator 100, while FIGS. 3B and 3C are schematic cross-sectional views taken along lines 3B-3B and 3C-3C, respectively, of FIG. 3A. As with the conventional acoustic wave lamb resonator 1 of FIGS. 1A-1C, in the schematic views of FIGS. 3A and 3B only a few of the electrode pairs that are formed in the active region are shown to simplify the figures.

As shown in FIGS. 3A-3C, the acoustic lamb wave resonator 100 includes a substrate 110 that has a recess 112 formed in an upper surface thereof. The substrate 110 may comprise, for example, a silicon substrate. The substrate 110 may be highly resistive in order to reduce RF losses, and preferably is formed of a material that is easily etched (in order to form the recess 112 in the substrate 110). The substrate 110 also preferably is formed of a material that is conducive to forming a high quality piezoelectric film on the substrate 110. Non-limiting examples of materials that are good options for the substrate 110 include silicon, gallium arsenide based materials (i.e., materials including at least gallium and arsenide), gallium nitride based materials, silicon carbide, sapphire and the like.

The substrate includes a recess 112 in an upper surface thereof. The recess 112 may be an air-filled recess. The recess 112 may be formed prior to the formation of a thin piezoelectric film 120 of the acoustic wave lamb resonator (discussed below) or, alternatively, may be formed after the thin piezoelectric film 120 is formed. The recess 112 may be filled with a sacrificial material 114. The recess 112 may be formed by chemical etching, although embodiments of the present invention are not limited thereto. In embodiments where the recess 112 is formed prior to the piezoelectric film 120, the recess 112 may be filled with a sacrificial material 114 to provide a planar surface on which the piezoelectric film 120 is deposited. The sacrificial material 114 may be a different material than the material of the substrate 110. For example, the substrate 110 may comprise a silicon substrate and the recess 112 may be filled with silicon oxide or a phosphate glass as a sacrificial material 114 that is removed in a later processing step.

A thin piezoelectric film 120 such as an aluminum nitride film or a scandium aluminum nitride film is provided above the recess 112. The piezoelectric film 120 may also extend directly onto the substrate 110, as shown. A metal signal bus 130 and a metal ground bus 140 are formed on an upper surface of the thin piezoelectric film 120 (i.e., opposite the recess 112). A plurality of signal electrodes 132 are formed on the piezoelectric film 120 that extend from the signal bus 130 toward the ground bus 140, and a plurality of ground electrodes 142 are formed on the piezoelectric film 120 that extend from the ground bus 140 toward the signal bus 130. The signal bus 130 and the ground bus 140 may extend in parallel to each other with their respective longitudinal axes extending in the width direction W of the acoustic lamb wave resonator 100. The signal electrodes 132 and the ground electrodes 142 may extend in parallel to each other with their respective longitudinal axes extending in the length direction L of the acoustic lamb wave resonator 100.

The signal and ground electrodes 132, 142 are much longer in the length direction L than in the width direction W. The signal bus 130 includes a plurality of signal stubs 134 that extend a short distance toward the ground bus 140. Each signal stub 134 is aligned in the length direction L with a respective one of the ground electrodes 142. The ground bus 140 includes a plurality of ground stubs 144 that extend a short distance toward the signal bus 130. Each ground stub 144 is aligned in the length direction L with a respective one of the signal electrodes 132. Gaps 136 separate each signal stub 134 from the respective ground electrode 142 with which it is aligned in the length direction L, and gaps 146 separate each ground stub 144 from the respective signal electrode 132 with which it is aligned in the length direction L.

As is further shown in FIGS. 3A-3C, a metal frame 160 is formed on the upper surfaces of the signal and ground electrodes 132, 142. The metal frame 160 includes a lower frame section 162-1 and an upper frame section 162-2. Each of the upper and lower frame sections 162-1, 162-2 comprises a plurality of spaced-apart metal segments 164. The metal segments 164 of the lower frame section 162-1 are formed on the distal ends of the signal electrodes 132 and on base regions of the ground electrodes 142, and the metal segments 164 of the upper frame section 162-2 are formed on the distal ends of the ground electrodes 142 and on base regions of the signal electrodes 132. Each metal segment 164 of the frame 160 may have the same extent in the width direction W as does the signal or ground electrode 132, 142 on which the metal segment 164 is formed. Fabricating the metal segments 164 of the frame 160 to have the same extent in the width direction W as the signal and ground electrodes 132, 142 may provide manufacturing efficiencies, although it will be appreciated that embodiments of the present invention are not limited thereto. For example, in other embodiments, the extent of each segment 164 in the width direction W may be less than the extent of each electrode 132, 142 in the width direction W. Each metal segment 164 has an extent in the length direction L that is much less than the length of the signal and ground electrodes 132, 142. It will also be appreciated that the metal segments 164 need not be positioned exactly at the base and/or distal end of the corresponding electrodes 132, 142, but instead may be shifted to a limited extent from the positions shown in the figures in the length direction L. For example, as shown in FIG. 3A, the metal segments 164 that are on the base regions of the signal and ground electrodes 132, 142 are offset from the respective signal and ground buses 130, 140, and hence are referred to as being on the “base regions” of the signal and ground electrodes 132, 142. The frame 160 is designed to suppress spurious resonances by reducing the coupling of electrical energy into mechanical modes.

The signal bus 130, the ground bus 140, and the outer ones of the signal/ground electrodes 132, 142 define an active region 102 of the acoustic lamb wave resonator 100, as shown by the dashed box in FIG. 3A. Inactive regions 104-1 and 104-2 are provided on opposed sides of the active region 102. A plurality of floating metal electrodes 152 are provided in each inactive region 104. Each floating electrode 152 has a longitudinal axis that extends in the length direction L, and lengths of the floating electrodes 152 may be the same as or similar to the lengths of signal electrodes 132 and the ground electrodes 142. The floating metal electrodes 152 may have the same pitch as the signal/ground electrodes 132/142 in the active region 102 (i.e., the center-to-center distance between adjacent floating electrodes 152 in each inactive region 104 may be the same as the center-to-center distance between a signal electrode 132 and an adjacent ground electrode 142 in the active region 102). The floating electrodes 152 in each inactive region 104 form respective acoustic grating reflectors 150 that enhance confinement of acoustic energy within the active region 102. In particular, each acoustic grating reflector 150 acts as an acoustic mirror that helps reflect the acoustic waves to keep them confined within the active region 102.

A supplemental metal frame 170 may also be provided by forming metal segments 174 on the upper surface of some or all of the floating electrodes 152. As shown, the metal segments 174 of the supplemental frame 170 may extend the full length of the floating electrodes 152 on which they are formed. The supplemental metal frame 170 may further help confine acoustic energy in the active region 102 and suppress generation of spurious modes.

The signal electrodes 132 and the ground electrodes 142 are spaced apart from one another in the width direction W in alternating fashion so that (except at the opposed side edges of the active region 102) a ground electrode 142 is provided on either side of each signal electrode 132, and a signal electrode 132 is provided on either side of each ground electrode 142. In other words, the signal electrodes 132 and the ground electrodes 142 are disposed in alternating fashion on the piezoelectric film 120.

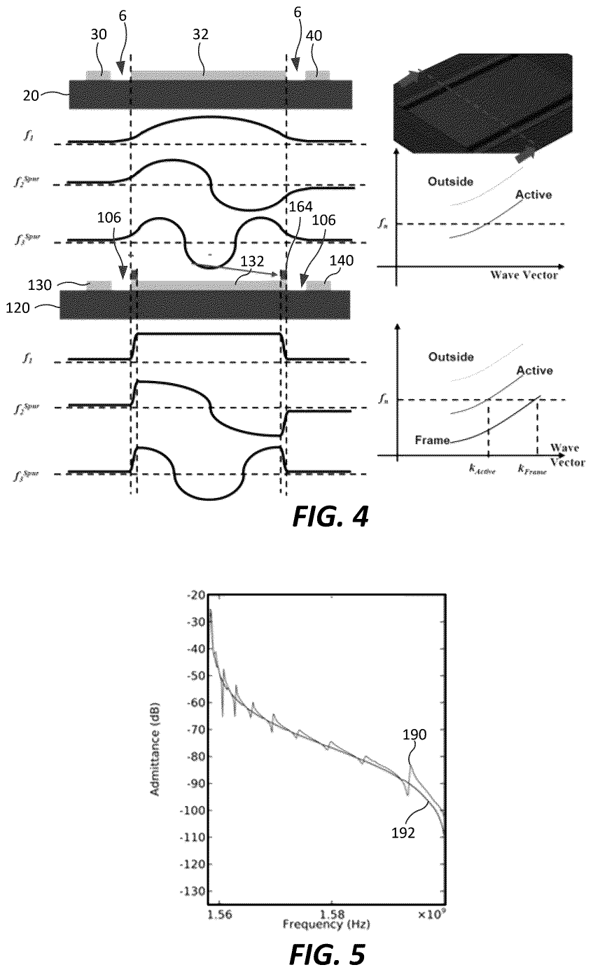

FIG. 4 is a schematic diagram illustrating how the acoustic lamb wave resonator 100 of FIGS. 3A-3C suppresses generation of spurious modes as compared to the conventional acoustic lamb wave resonator 1 of FIGS. 1A-1C. Schematic cross-sectional views of the conventional acoustic lamb wave resonator 1 and the acoustic lamb wave resonator 100 according to embodiments of the present invention are shown in the upper and lower left insets of FIG. 4, respectively. The perspective view in the upper right inset of FIG. 4 illustrates the cut line for the two cross-sectional diagrams on the left side of FIG. 4.

As shown in the graphs in the upper left portion of FIG. 4, in the conventional acoustic lamb wave resonator 1, in the regions just outside the active region 2 where the gaps 36, 46 are provided between the signal and ground electrodes 32, 42 and the signal and ground buses 30, 40 (herein, this region is referred to as the gap region 6), the coverage of the piezoelectric film 20 by the signal and ground electrodes 32, 42 decreases per unit area due to the presence of the gaps 36, 46. This results in less mass-loading of the piezoelectric film 20. As the velocity of an acoustic wave is inversely proportional to the square root of density, the dispersion outside the gap region 6 is shifted to higher frequencies, leading to mode cut-off at frequencies of the spurious modes. As a result, the spurious mode profile exhibits an evanescent tail profile outside of the gap region 6 and a sinusoidal standing wave profile within the gap region 6. As the material of the piezoelectric film 20 is homogeneous, and the excitation field is approximately uniform in the length direction L within the active region 2, the overlap integral between the uniform excitation field and the mode profile of any spurious modes that have an even number of anti-nodes tends to zero since the regions outside of the phase displacement field cancel out. However, this is not the case for modes with an odd number of anti-nodes in the length direction L. In addition, as the order of the odd order spurious modes increases, the energy coupling tends to zero, as the portion of the overlap integral that does not cancel out tends to zero. This observation is leveraged here to suppress spurious modes.

As shown in the bottom left inset of FIG. 4, the acoustic wave lamb resonator according to embodiments of the present invention includes a frame 160 at the edges of the gap region 6. The frame 160 is located in a frame region that is inward of the gap region 6. As will be discussed in greater detail below, the frame 160 may be implemented by selectively providing a second metal layer on end regions of the signal and ground electrodes 132, 142. In some embodiments, the frame 160 and the signal and ground electrodes 132, 142 may be formed as a heterogeneous bi-layer metal. In one example embodiment, the signal and ground electrodes 132, 142 may comprise aluminum electrodes and the frame 160 may comprise a plurality of tungsten segments 164 that are formed on the aluminum electrodes 132, 142 opposite the piezoelectric film 120 to form upper and lower frame sections 162-1, 162-2 that each comprise a plurality of spaced-apart segments 164 that may be aligned along the width direction W. These tungsten segments 164 may provide significant mass-loading and, as a result, the dispersion in the frame region is shifted to lower frequencies. This causes the wave vector component in the length direction L for the wave profile in the frame region (k_{Frame}) to be significantly higher than the wave vector component in the length direction L for the wave profile in the active region (k_{Active}). A proper choice of the dimension of the frame 160 in the length direction L for a given thickness of the frame segments 164 (hence the wave vector value in the frame region) leads to a mode profile as shown in the bottom left inset of FIG. 4. Moreover, the boundary condition may be enforced so that the overlap integral between the excitation field and all transverse spurious modes tends to zero. It should be noted that the overlap integral in the frame region for transverse modes with odd numbers of anti-nodes do not cancel. Therefore, the frame 160 should be designed so that the segments 164 thereof only extend a small percentage of the length of the signal and ground electrodes 132, 142 in the length direction L, so that the energy coupling from the frame 160 to the spurious modes is minimal.

FIG. 5 is a graph that illustrates how the acoustic wave lamb filters according to embodiments of the present invention may suppress spurious modes. As shown by curve 190 in FIG. 5, the response of a conventional lamb wave resonator has significant ripple due to spurious modes, with many of the ripples exceeding 5 dB or even 10 dB. As shown by curve 192 in FIG. 5, by adding the above-described frame 160, the transverse spurs are almost completely suppressed (suppression of more than 10 dB). Optimum spur suppression may be achieved when the displacement profiles of the spurious modes at the end (toward the center of the device) of the frame regions exhibits a mechanical anti-node. This is determined by the size of the frame region as well as the dispersion in the frame region as controlled by the thickness of the metal frame 160. With fine tuning of the geometry of the frame 160, almost complete spurious mode suppression may be achieved.

A number of factors may be considered in implementing the frame 160 for transverse spur suppression.

First, the material used to form the signal and ground electrodes 132, 142 (and the signal and ground buses 130, 140) preferably exhibits low electrical resistivity and low acoustic damping so that the acoustic wave lamb resonator 100 will have a high resonator quality factor. For example, while gold has low electrical resistivity, acoustic damping in gold is high, and hence gold is not a preferred option for implementing the signal and ground electrodes 132, 142. Similarly, tungsten is not a good option due to its high electrical resistivity. Aluminum, on the other hand, has both low electrical resistivity and low acoustic damping, and also is inexpensive and readily available, and hence is a good option for forming the signal and ground electrodes 132, 142. Other materials may be used.

Second, high density material that exhibits low acoustic damping may be well-suited for use as the material of the frame 160 to enhance frequency down-shift of the dispersion in the region bordered by the frame 160 and the grating reflectors 150, which helps reduce the size of the region bordered by the frame 160 and the grating reflectors 150 needed to optimize spur suppression. If a low-density material is used, increased frame thickness (in the depth direction D) is needed to frequency down-shift the dispersion. This leads to a large physical step from the supper surfaces of the signal and ground electrodes 132, 142 to the upper surface of the frame 160. Such a large step may disrupt the boundary condition. In addition, a large step may be more challenging to implement using standard microfabrication techniques and hence may negatively impact yield or make it difficult to meet tight alignment tolerances. Thus, tungsten is a good choice for the material for the metal frame 160, although other materials may be used.

Third, the frame 160 can be physically constructed with a manufacturable microfabrication process. For example, it is not trivial to have a microfabricated frame region with accurately controlled thicknesses and/or that aligns perfectly with the signal and ground electrodes 132, 142. Misalignment of the frame 160 may lead to acoustic energy scattering that degrades quality factor of the acoustic lamb wave resonator and/or may generate spurious modes.

Due to the disparate requirements set forth above, the acoustic lamb wave resonators according to embodiments of the present invention, may employ a heterogeneous bi-layer metallization structure on the piezoelectric layer 120 that comprises a first (lower) layer in which the electrodes and buses 130, 132, 140, 142 are formed and a second (upper) letter that comprises the frame 160. The first layer of the bi-layer metallization structure may be formed directly on the upper surface of the piezoelectric material 120. The second layer of the bi-layer metallization structure is selectively formed on the upper surface of the first layer. In some embodiments, the first layer may comprise a patterned aluminum layer and the second layer may comprise a patterned tungsten layer. The lower aluminum layer is part of the active transducer, and the low resistivity and low acoustic damping properties of aluminum may enhance the performance of the acoustic lamb wave resonator 100. The upper tungsten layer forms the frame 160 and acts as a mass-loading layer due to its high density and low acoustic damping. Advantageously, tungsten can be selectively removed from aluminum using hydrogen peroxide which enables self-aligning the frame 160 with the signal electrodes 132, the ground electrodes 142 and the floating electrodes 152.

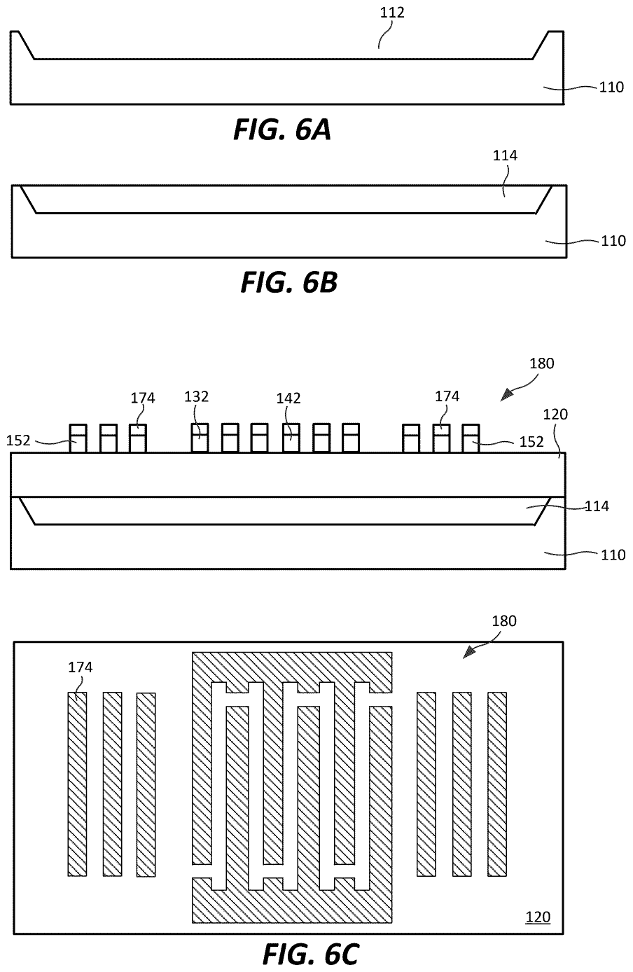

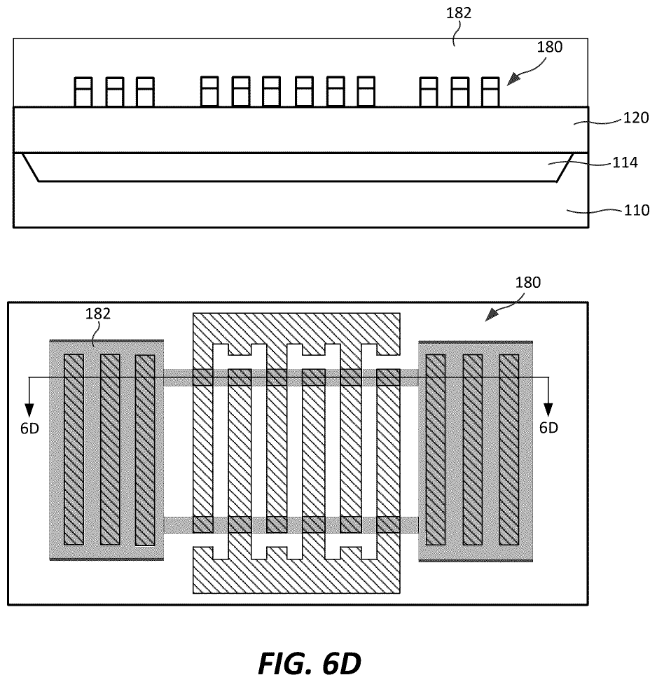

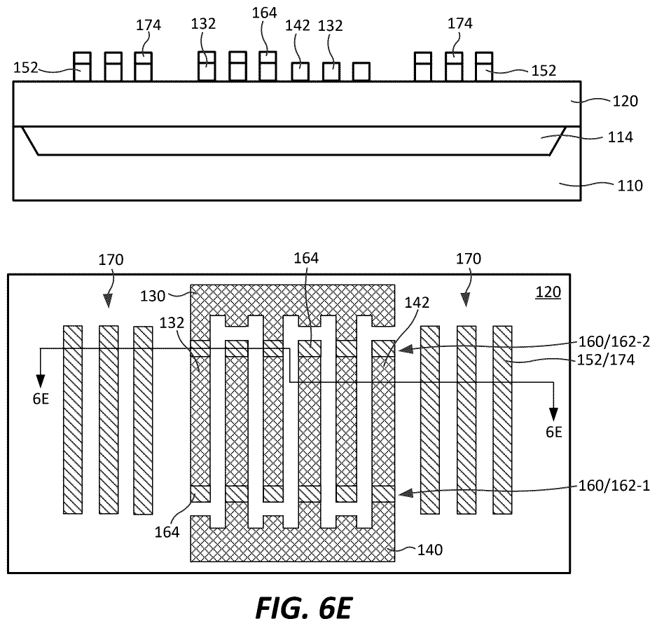

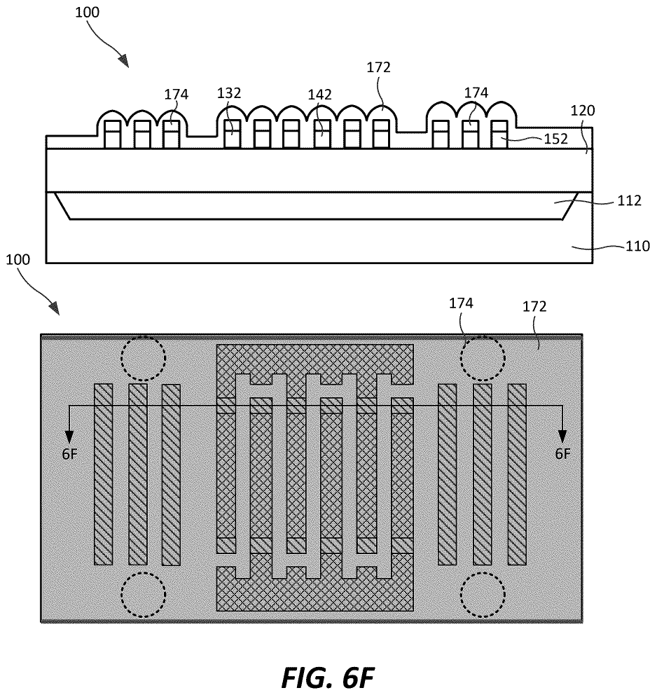

FIGS. 6A and 6B are cross-sectional views that illustrate certain steps of a microfabrication process for manufacturing acoustic wave lamb filters according to embodiments of the present invention, and FIGS. 6C-6F each include a schematic top view and a schematic cross-sectional view to illustrate further steps of the method of manufacturing the acoustic lamb wave resonators according to embodiments of the present invention.

As shown in FIG. 6A, a substrate 110 such as a high resistivity silicon substrate is provided. One or more recesses 112 are formed in the upper surface of the silicon substrate 110.

Referring to FIG. 6B, the recess 112 is filled with a sacrificial material 114 such as silicon oxide or phosphate glass. The upper surface of the silicon substrate 110 with the sacrificial material 114 formed in the recess 122 may be planarized to have a flat surface, as shown.

Referring to FIG. 6C, next, a piezoelectric layer 120 is formed on the upper surface of the silicon substrate 110 with the sacrificial material 114 formed in the recess 112.

The piezoelectric layer 120 may be formed, for example, by sputtering or molecular beam epitaxy. The piezoelectric layer 120 may be a scandium aluminum nitride layer or an aluminum nitride layer in example embodiments. An aluminum layer is blanket deposited on the piezoelectric layer 120 by, for example, sputtering. Next, a tungsten layer is blanket deposited on the aluminum layer by, for example, sputtering. A bi-metal-layer lift-off process is then performed to provide a metal pattern 180 that includes metal structures that will correspond to the signal bus 130, the signal electrodes 132, the ground bus 140, the ground electrodes 142 and the floating electrodes 152 in the completed device 100. As the metal pattern 180 is formed via a single lift-off step, the tungsten structures 164, 174 are perfectly self-aligned with the underlying aluminum structures, and the thickness of both layers may be accurately controlled during the deposition process.

Referring to FIG. 6D, a photoresist mask 182 is formed that covers the floating electrodes 152 and end portions of the signal electrodes 132 and the ground electrodes 142 on which the tungsten frame will be formed.

Referring to FIG. 6E, a hydrogen peroxide etch is performed using the photoresist mask 182 as an etching mask. As hydrogen peroxide has very high etch selectivity between tungsten and aluminum (greater than 500:1), the hydrogen peroxide will effectively remove the tungsten from the portions of the aluminum pattern that are not covered by the photoresist mask 182. As such, the etching step forms the tungsten frame 160 on the end regions of the signal and ground electrodes 132, 142. As is also shown in FIG. 6E, the photoresist mask 182 may also cover the floating electrodes 152 so that the tungsten segments 174 will also remain on the floating electrodes 152 after the hydrogen peroxide etch. The tungsten on the floating electrodes 152 may form a supplemental frame 170 that may optionally be provided in some embodiments of the present invention.

Referring to FIG. 6F, a silicon nitride passivation layer 172 may be blanket deposited on the upper surface of the device 100. In addition, one or more openings 174 are formed in the piezoelectric layer 120 using, for example, a reactive ion etch. Argon ion beam trimming of the silicon nitride passivation layer 172 may then be performed using a photoresist mask as a mask to set the thickness of the silicon nitride covering the active region 102 to fine tune the resonant frequency. Finally, the device 100 is immersed in diluted hydrofluoric acid to selectively remove the sacrificial material 114 in the recesses 112 so that both major surfaces of the piezoelectric layer 120 will have a solid-to-air boundary, thereby providing a suspended thin film device.

As described above, a self-aligned process may be used to form the signal bus 130, signal electrodes 132, the ground bus 140, the ground electrodes 142, the floating electrodes 152, the frame 160 and the supplemental frame 170. In some embodiments, the signal bus 130, signal electrodes 132, the ground bus 140, the ground electrodes 142, and the floating electrodes 152 may all be formed of aluminum (or an aluminum alloy) because aluminum exhibits low resistivity which facilitates efficiently exciting the acoustic waves and also exhibits low acoustic loss. Aluminum is also inexpensive and readily available. It will be appreciated, however, that numerous other metals may be used to form the signal bus 130, signal electrodes 132, ground bus 140, ground electrodes 142, and floating electrodes 152 including, for example, copper and platinum. In some embodiments, the frame 160 and the supplemental frame 170 may be formed of tungsten because tungsten has a high density and exhibits low acoustic loss, which facilitates a significant shift in dispersion on the frame region, which improves spur suppression performance. It will be appreciated, however, that numerous other metals may be used to form the frame 160 and the supplemental frame 170 such as, for example, molybdenum.

As is also discussed above, there may be manufacturing advantages to having the metal segments 164 of the frame 160 be aligned at the tips of the signal and ground electrodes 132, 142, as this allows the electrodes 132, 142, 152 and the frames 160, 170 to be formed on the piezoelectric layer 120 using a two-step deposition process that employs the same photoresist mask, which results in the two metal layers being self-aligned. Thereafter, the upper metal layer may be selectively etched using a second lithography step and a selective etching chemistry (e.g., H₂O₂) that does not appreciably etch the lower metal layer in order to remove portions of the upper metal layer that are not needed. Such a process efficiently and effectively provides a bi-layer structure that may have perfect alignment. While such a structure could also be fabricated using multiple photolithography steps, this may be difficult in practice (e.g. due to challenging photolithography alignment between steps) and requires extra manufacturing steps with no additional benefit.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of an acoustic wave resonator are considered to “vertically overlap” if an axis that is perpendicular to the major surfaces of a substrate of the acoustic wave resonator intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes,” “including” and “having” when used herein, specify the presence of stated features, elements, and/or components, but do not preclude the presence or addition of one or more other features, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical embodiments of the invention and, although specific terms are employed, they are used in a generic and descriptive sense only and not for purposes of limitation, the scope of the invention being set forth in the following claims.

1. An acoustic lamb wave resonator, comprising:
a substrate having a recess;
a piezoelectric layer that at least partially covers the recess;
a plurality of metal electrodes on the piezoelectric layer, each metal electrode comprising a first metal; and
a plurality of second metal segments that comprise a second metal that is different than the first metal, the second metal segments on respective ones of at least some of the metal electrodes opposite the piezoelectric layer.

2. The acoustic lamb wave resonator of claim 1, wherein the acoustic lamb wave resonator has an active region and an inactive region, and the metal electrodes are within the active region.

3. (canceled)

4. The acoustic lamb wave resonator of claim 1, wherein the second metal comprises tungsten.

5. The acoustic lamb wave resonator of claim 4, wherein the first metal comprises aluminum.

6. The acoustic lamb wave resonator of claim 1, wherein the second metal segments form a frame.

7. The acoustic lamb wave resonator of claim 1, further comprising a signal bus and a ground bus, wherein the plurality of metal electrodes comprise:
a plurality of signal electrodes that are physically and electrically connected to the signal bus; and
a plurality of ground electrodes that are physically and electrically connected to the ground bus.

8. The acoustic lamb wave resonator of claim 7, wherein a first subset of the second metal segments are on distal ends of the respective signal electrodes, a second subset of the second metal segments are on base regions of the respective signal electrodes, a third subset of the second metal segments are on distal ends of the respective ground electrodes, and a fourth subset of the second metal segments are on base regions of the respective ground electrodes.

9. The acoustic lamb wave resonator of claim 8, wherein the second metal segments in the first subset and the fourth subset are aligned along a first axis, and the second metal segments in the second subset and the third subset are aligned along a second axis.

10. (canceled)

11. The acoustic lamb wave resonator of claim 2, further comprising a first plurality of floating electrodes on the piezoelectric layer and a second plurality of floating electrodes on the piezoelectric layer on respective opposed sides of the active region, each floating electrode comprising the first metal, the acoustic lamb wave resonator further comprising a supplemental metal frame, the supplemental metal frame comprising a plurality of additional second metal segments, where each additional second metal segment comprises the second metal and is on a respective one of the floating electrodes opposite the piezoelectric layer.

12-13. (canceled)

14. The acoustic lamb wave resonator of claim 6, wherein each of the metal electrodes extends along a respective longitudinal axis, where the longitudinal axes extend in a length direction of the acoustic lamb wave resonator, and wherein a length of each second metal segment in the length direction is set so that displacement profiles of the spurious modes at the end of the frame exhibit a mechanical anti-node.

15-16. (canceled)

17. The acoustic lamb wave resonator of claim 1, wherein the second metal has a higher density than the first metal.

18. The acoustic lamb wave resonator of claim 1, wherein each of the metal electrodes extends along a respective longitudinal axis, where the longitudinal axes extend in a length direction of the acoustic lamb wave resonator, and wherein each second metal segment is stacked on a respective one of the metal electrodes in a depth direction and has a width in a width direction that is the same as the width of the metal electrode on which it is stacked, where the length, width and depth directions are perpendicular to each other.

19. (canceled)

20. An acoustic lamb wave resonator, comprising:
a substrate having a recess;
a piezoelectric layer that at least partially covers the recess;
a plurality of metal electrodes on the piezoelectric layer, the metal electrodes defining an active region; and
a first metal frame section on a first side of the active region, the first metal frame section comprising a first plurality of spaced-apart frame segments on respective ones of the metal electrodes.

21. The acoustic lamb wave resonator of claim 20, wherein each metal electrode comprises a first metal, and each frame segment comprises a second metal that is different than the first metal.

22. The acoustic lamb wave resonator of claim 21, wherein the second metal has a higher density than the first metal, and wherein the second metal has a higher resistivity than the first metal.

23-24. (canceled)

25. The lamb wave resonator of claim 22 , further comprising a second metal frame section on a second side of the active region that is opposite the first side, the second metal frame section comprising a second plurality of spaced-apart frame segments on respective ones of the metal electrodes.

26. The acoustic lamb wave resonator of claim 20, wherein each metal electrode is in between a respective one of the frame segments in the first plurality of spaced-apart frame segments and the piezoelectric layer.

27. An acoustic lamb wave resonator, comprising:
a substrate having a recess;
a piezoelectric layer that at least partially covers the recess, where the piezoelectric layer includes an active region and an inactive region; and
a plurality multi-layer metal structures on the piezoelectric layer in the active region, where each multi-layer metal structure includes a first layer that comprises a first metal that directly contacts the piezoelectric layer and a second layer that comprises a second metal that is different than the first metal on the first layer opposite the piezoelectric layer.

28. The acoustic lamb wave resonator of claim 27, wherein the second layer only partially covers the first layer.

29-30. (canceled)

31. The acoustic lamb wave resonator of claim 27, wherein the first layer comprises a plurality of electrodes, and the second layer comprises a plurality of metal segments that are formed on opposed ends of each electrode.

32-39. (canceled)
